(19) United States
(12) Patent Application Publication
(10) Pub. No.: US 2025/0151424 A1
(43) Pub. Date: May 8, 2025

(54) CIS PIXEL READOUT STRUCTURE AND METHOD FOR FABRICATING THE SAME

(71) Applicant: Shanghai Huali Integrated Circuit Corporation, Shanghai (CN)

(72) Inventors: Qiwei WANG, Shanghai (CN); Zhen Gu, Shanghai (CN); Haoyu Chen, Shanghai (CN); Lei Zhang, Shanghai (CN); Zhi Tian, Shanghai (CN)

(73) Assignee: Shanghai Huali Integrated Circuit Corporation, Shanghai (CN)

(21) Appl. No.: 18/783,225

(22) Filed: Jul. 24, 2024

(30) Foreign Application Priority Data
Nov. 7, 2023 (CN) 202311474748.0

(51) Int. Cl. H01L 27/146; H04N 25/77

(52) U.S. Cl. CPC H10F 39/18; H04N 25/77; H10F 39/014; H10F 39/8037

(57) ABSTRACT

This application discloses a CIS pixel readout structure. An SF and an SG adopt an asymmetric spacer structure, so that the pitch from a lower end of a source metal plug of the SG to SG gate poly can be reduced while keeping the pitch from a lower end of a drain metal plug of the SF to SF gate poly unchanged, thus reducing the pitch from a drain connecting point of the SF to a source connecting point of the SG. Since a source of the SG is not connected with working voltage and it is not influenced by leakage, not only can GIDL current be maintained, but also parasitic resistance can be reduced. Without changing its effective size, it can reduce the parasitic resistance effect while reducing the area of a combined structure of the SF and the SG.

### CROSS-REFERENCE TO RELATED APPLICATIONS

This application claims priority to Chinese patent application No. 202311474748.0, filed on Nov. 7, 2023, the disclosure of which is incorporated herein by reference in its entirety.

### TECHNICAL FIELD

This application relates to a semiconductor manufacturing technology, and in particular to a CIS pixel readout structure and a method for fabricating the same.

### BACKGROUND

A CMOS Image Sensor (CIS) is composed of a pixel unit circuit and a CMOS circuit. The pixel unit circuit is located in a pixel area. The CMOS circuit is a logic circuit located in a logic area. Compared with Charge-coupled Device (CCD) image sensors, MOS image sensors have better integration capabilities due to the use of a CMOS standard fabrication process, which can be integrated with other digital and analog operation and control circuits on the same chip, and are more suitable for future development. According to the number of transistors contained in the pixel unit circuits of the existing CMOS image sensors, they are mainly divided into 3T CMOS image sensors and 4T CMOS image sensors.

FIG. 1 illustrates an equivalent circuit diagram of a pixel unit circuit of a typical 3T CMOS image sensor, which includes a photodiode (PD) D1 and a CMOS pixel readout circuit. The CMOS pixel readout circuit is a 3T type pixel circuit, including a reset transistor M1, a source follower transistor (SF) M2 and a select transistor (SG) M3, all of which are NMOS transistors. An N-type area of the photodiode D1 is connected with a source of the reset transistor M1. A gate of the reset transistor M1 is connected with a reset signal Reset. The reset signal Reset is a potential pulse. When the reset signal Reset is at a high level, the reset transistor M1 is conducted and absorbs electrons of the photodiode D1 into a power supply Vdd of the readout circuit to achieve reset. When illuminated by light, the photodiode D1 generates photo-induced electrons, the potential increases, and the electrical signal is transmitted through an amplification circuit. A gate of the select transistor M3 is connected with a line select signal RS and used for selecting to output the amplified electrical signal as an output signal Vout.

FIG. 2 illustrates an equivalent circuit diagram of a pixel unit circuit of a typical 4T CMOS image sensor. The difference from the structure illustrated in FIG. 1 is that there is an additional transfer transistor or pass transistor M4 in the structure illustrated in FIG. 2. A source area of the transfer transistor M4 is an N-type area connected with the photodiode D1. A drain area of the transfer transistor M4 is a Floating Diffusion (FD) area. A gate of the transfer transistor M4 is connected with a transmission control signal Tx. After the photodiode D1 generates photo-induced electrons, they are transferred to the floating diffusion area through the transfer transistor M4, and then connected to the gate of the source follower transistor (SF) M2 through the floating diffusion area to achieve signal amplification.

With the continuous reduction of pixel units, the space for placing a combined structure of the source follower transistor (SF) and the select transistor (SG) is also getting smaller and smaller. A decrease in the width of the source follower transistor (SF) will lead to a decrease in transconductance (Gm), which will influence the noise of the CMOS image sensor. Even if W/L is proportionally reduced and the transconductance (Gm) remains unchanged, due to the decrease in W*L size, 1/f noise will increase. As nodes shrink, the space that an SF and an SG can reduce becomes smaller and smaller. As pixels shrink, all spaces will be fully utilized to maintain the performance of the combined structure of the SF and the SG.

A combined structure of a source follower transistor (SF) and a select transistor (SG) of an existing CIS pixel readout structure is as illustrated in FIG. 3. The pitch from a drain connecting point of the SF to a source connecting point of the SG is relatively large, making it difficult to reduce the parasitic resistance effect while reducing the area of the combined structure of the SF and the SG without changing its effective size (length and width of the device).

### BRIEF SUMMARY

This application provides a CIS pixel readout structure, wherein a P-well 100 is formed at an upper part of a semiconductor substrate;
SF gate poly and SG gate poly are formed on the P-well 100;
the SG gate poly is located on a left side of the SF gate poly; a space exists between the SG gate poly and the SF gate poly, and the left-right width L2 of the SF gate poly is greater than the left-right width L1 of the SG gate poly;
the space is filled with silicon oxide;
the transverse thickness of a spacer on a right side of the SF gate poly is greater than the transverse thickness of a spacer on a left side of the SG gate poly;
a drain metal plug of an SF is formed on a right side of a right spacer of the SF and used for being externally connected with working voltage Vdd;
a gate metal plug of the SG communicated to the SF gate poly is formed above the SF gate poly;
a source metal plug of an SG is formed on a left side of a left spacer of the SG and used for outputting CIS pixel readout voltage Vout;
a gate metal plug of the SG communicated to the SG gate poly is formed above the SG gate poly.

In some embodiments, a source N+ area is formed on a surface of the P-well on the left side of the left spacer of the SG gate poly;
a lower end of the source metal plug of the SG is connected to the source N+ area;
a drain N+ area is formed on a surface of the P-well on the right side of the right spacer of the SF gate poly;
a lower end of the drain metal plug of the SF is connected to the drain N+ area.

In some embodiments, the pitch CT1 from the lower end of the source metal plug of the SG to the SG gate poly is less than the pitch CT2 from the lower end of the drain metal plug of the SF to the SF gate poly.

In some embodiments, the left spacer of the SG gate poly is formed by transversely stacking a first spacer oxide layer 151 on a first spacer SiN layer 152;
the right spacer of the SF gate poly is formed by transversely stacking a first spacer SiN layer 152 on a second spacer oxide layer 153 and then transversely stacking a first spacer oxide layer 151;
the transverse thickness of the second spacer oxide layer is 10 Å-500 Å;
the space between the SG gate poly and the SF gate poly is less than 500 Å.

This application also provides a method for fabricating a CIS pixel readout structure, which include the following steps:
S0: performing a P-well process on a semiconductor substrate to form a common P-well for a source follower transistor (SF) and a select transistor (SG);
S1: sequentially forming a gate oxide layer 110, a poly layer 120 and a hard mask layer 130 on the semiconductor substrate;
S2: performing a photolithography process and etching, and removing the poly layer 120 around an SF gate area and an SG gate area to form gate structures, the SG gate structure being located on a left side of the SF gate structure; a space existing between the SG gate structure and the SF gate structure, the left-right width L2 of the SF gate structure being greater than the left-right width L1 of the SG gate structure;
S3: depositing a first spacer oxide layer 151, the first spacer oxide layer 151 filling the space between the SG gate structure and the SF gate structure;
S4: depositing a first spacer SiN layer 152;
S5: depositing a second spacer oxide layer 153;
S6: etching the second spacer oxide layer 153 till the first spacer SiN layer 152, reserving the second spacer oxide layer 153 on side surfaces of the gate structures, and removing the second spacer oxide layer 153 at other positions;
S7: performing a photolithography process and wet etching by using the first spacer SiN layer 152 as a stop layer, removing the second spacer oxide layer 153 on the side surface of the SG gate structure, and reserving the second spacer oxide layer 153 on the side surface of the SF gate structure to form an asymmetric structure;
S8: etching the first spacer SiN layer 152, reserving the first spacer SiN layer 152 on the side surfaces of the gate structures, and removing the first spacer SiN layer 152 at other positions to form an asymmetric spacer structure on a left side of the SG gate structure and a right side of the SF gate structure, a spacer on the left side of the SG gate structure being formed by transversely stacking a first spacer oxide layer 151 on a first spacer SiN layer 152, a spacer on the right side of the SF gate structure being formed by transversely stacking a first spacer SiN layer 152 on a second spacer oxide layer 153 and then transversely stacking a first spacer oxide layer 151;
S9: forming a drain metal plug and a gate metal plug of the SF, and a source metal plug and a gate metal plug of the SG,
the drain metal plug of the SF being located on a right side of a right spacer of the SF and used for being externally connected with working voltage Vdd;
the gate metal plug of the SG being communicated to the poly layer 120 of the SF;
the source metal plug of the SG being located on a left side of a left spacer of the SG and used for outputting CIS pixel readout voltage Vout;
the gate metal plug of the SG being communicated to the poly layer 120 of the SG; and
S10: performing subsequent processes.

In some embodiments, the pitch CT1 from a lower end of the source metal plug of the SG to the poly layer 120 of the SG is less than the pitch CT2 from a lower end of the drain metal plug of the SF to the poly layer 120 of the SF.

In some embodiments, in step S1, the hard mask layer 130 is a composite structure formed by stacking a mask SiN layer 132 on a mask oxide layer 131.

In some embodiments, step S2 includes the following steps:
S21: performing a photolithography process and etching the mask SiN layer 132 till the mask oxide layer 131;
S22: depositing a space SiN layer 133;
S23: etching the space SiN layer 133 till the mask oxide layer 131 to cover a peripheral side of the mask SiN layer 132 with the space SiN layer 133; and
S24: etching the mask oxide layer 131 and the poly layer 120 till the gate oxide layer 110 to form gate structures.

In some embodiments, after step S24, Rapid Thermal Oxidation (RTO) treatment is firstly performed on gate poly to form side protection for the gate poly and repair etching damage of the gate poly, and then step S3 is performed.

In some embodiments, the space between the SG gate structure and the SF gate structure is less than 500 Å.

In some embodiments, the transverse thickness of the second spacer oxide layer is 10 Å-500 Å.

In some embodiments, after step S2, a self-aligned LDD implantation process is performed by using a hard mask layer 130 to form a drain LDD of the SF on a surface of the P-well 100 at a right end of the SF gate structure and form a source LDD of the SG on a surface of the P-well 100 at a left end of the SG gate structure; then step S3 is performed.

In some embodiments, after LDD implantation is completed, SiN is removed through wet etching; then step S3 is performed.

In some embodiments, step S9 includes the following steps:
S91: performing N+ (N-type heavily doped) ion implantation by adopting a self-alignment method to form a drain N+ area of the SF on a surface of the drain LDD of the SF and form a source N+ area of the SG on a surface of the source LDD of the SG; defining different pitches from the drain N+ area of the SF and the source N+ area of the SG to a channel through a difference between the transverse thickness of the spacer on the right side of the SF and the transverse thickness of the spacer on the left side of the SG; and
S92: through an interlayer dielectric process and a contact process, forming a drain metal plug of the SF communicated to the drain N+ area on the right side of the right spacer of the SF;
forming a gate metal plug of the SF communicated to the SF gate poly above the SF gate poly;
forming a source metal plug of the SG communicated to the source N+ area on the left side of the left spacer of the SG; and
forming a gate metal plug of the SG communicated to the SG gate poly above the SG gate poly.

In some embodiments, in step S92, the interlayer dielectric process includes firstly depositing a silicide-blocked (SAB) oxide layer 162; then depositing a Contact Etch Stop Layer (CESL) 161; and then depositing an ILD (interlayer dielectric) 163 and performing chemical-mechanical polishing.

In the CIS pixel readout structure according to this application, the SG and SF adopt different transverse thicknesses of spacers. The spacer of the SG adopts a smaller transverse thickness, thus reducing the parasitic resistance. The spacer of the SF adopts a larger transverse thickness, thus reducing the Gate-Induced Drain Leakage (GIDL) current. In the CIS pixel readout structure, the SF and the SG adopt the asymmetric spacer structure, so that the pitch CT1 from the lower end of the source metal plug of the SG to the SG gate poly can be reduced while keeping the pitch CT2 from the lower end of the drain metal plug of the SF to the SF gate poly unchanged, thus reducing the pitch from the drain connecting point of the SF to the source connecting point of the SG. Since the source of the SG is not connected with working voltage Vdd and it is not influenced by leakage, not only can the GIDL current be maintained, but also the parasitic resistance can be reduced. Without changing its effective size (length and width of the device), it can reduce the parasitic resistance effect while reducing the area of the combined structure of the SF and the SG, thus effectively improving the transconductance (Gm) and reducing the imaging noise.

### BRIEF DESCRIPTION OF THE DRAWINGS

In order to more clearly describe the technical solutions in this application, the following will briefly introduce the drawings needed in this application. It is obvious that the drawings in the following description are only some embodiments of this application. Those skilled in the art may obtain other drawings from these drawings without contributing any inventive labor.

FIG. 1 illustrates an equivalent circuit diagram of a pixel unit circuit of a typical 3T CMOS image sensor.

FIG. 2 illustrates an equivalent circuit diagram of a pixel unit circuit of a typical 4T CMOS image sensor.

FIG. 3 illustrates a schematic diagram of a combined structure of a source follower transistor (SF) and a select transistor (SG) of an existing CIS pixel readout structure.

FIG. 4 to FIG. 21 illustrate schematic diagrams in steps of a method for fabricating a CIS pixel readout structure according to an embodiment of this application.

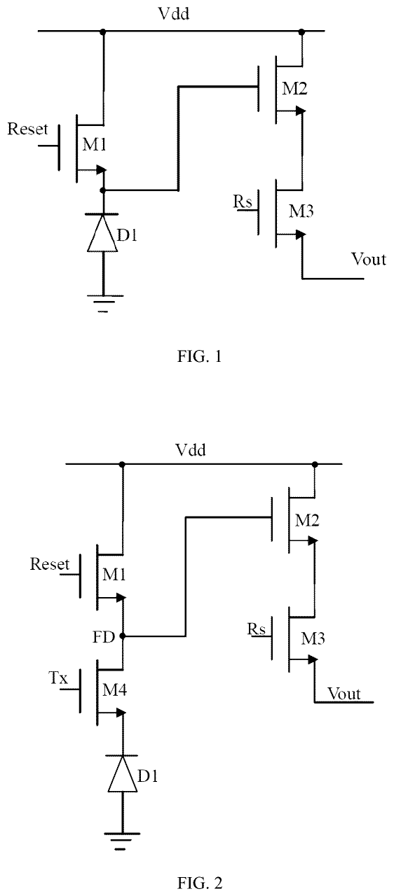

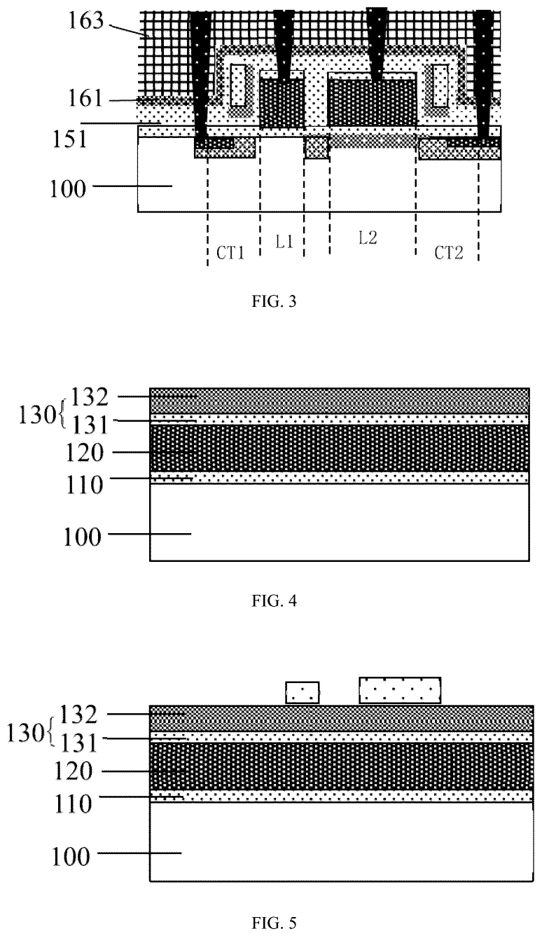

Description of reference signs:

100—P-well; 110—gate oxide layer; 120—poly layer; 130—hard mask layer; 131—mask oxide layer; 132—mask SiN layer; 133—space SiN layer; 151—first spacer oxide layer; 152—first spacer SiN layer; 153—second spacer oxide layer; 161—contact etch stop layer; 162—silicide-blocked oxide layer; 163—interlayer dielectric.

### DETAILED DESCRIPTION OF THE EMBODIMENTS

The technical solutions in the embodiments of this application will be clearly and completely described below with reference to the drawings in the embodiments of this application. Apparently, the described embodiments are merely some rather than all of the embodiments of this application. All other embodiments obtained by those skilled in the art based on the embodiments of this application without contributing any inventive labor shall still fall within the scope of protection of this application.

Words such as “first”, “second” and the like used in this application do not indicate any order, quantity, or importance, but are only intended to distinguish different components. Words such as “comprising”, “including” and the like refer to a component or object that appears before the word including those listed after the word and their equivalents, without excluding other components or objects. Words such as “connecting”, “connected” and the like are not limited to physical or mechanical connection, but can include electrical connection, whether direct or indirect. “Up”, “down”, “left”, “right”, “front”, “back” and the like are only intended to represent relative positional relationships. When the absolute position of a described object changes, the relative positional relationship may also change accordingly.

It is to be understood that, without conflict, the embodiments and features in the embodiments of this application may be freely combined with each other.

### Embodiment 1

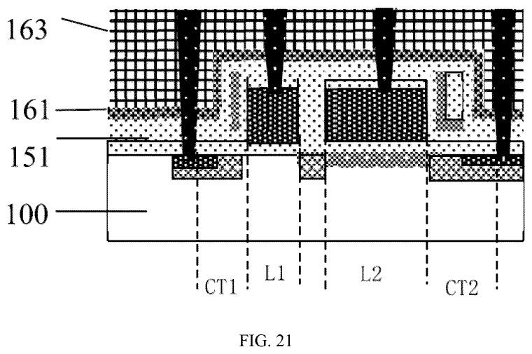

Provided is a CIS pixel readout structure. Referring to FIG. 21, a P-well 100 is formed at an upper part of a semiconductor substrate.

Source follower transistor (SF) gate poly and select transistor (SG) gate poly are formed on the P-well 100.

The SG gate poly is located on a left side of the SF gate poly. A space exists between the SG gate poly and the SF gate poly. The left-right width L2 of the SF gate poly is greater than the left-right width L1 of the SG gate poly;

The space is filled with silicon oxide.

The transverse thickness of a spacer on a right side of the SF gate poly is greater than the transverse thickness of a spacer on a left side of the SG gate poly.

A drain metal plug of an SF is formed on a right side of a right spacer of the SF and used for being externally connected with working voltage Vdd.

A gate metal plug of the SG communicated to the SF gate poly is formed above the SF gate poly.

A source metal plug of an SG is formed on a left side of a left spacer of the SG and used for outputting CIS pixel readout voltage Vout.

A gate metal plug of the SG communicated to the SG gate poly is formed above the SG gate poly.

In the CIS pixel readout structure according to embodiment 1, the SG and SF adopt different transverse thicknesses of spacers. The spacer of the SG adopts a smaller transverse thickness, thus reducing the parasitic resistance. The spacer of the SF adopts a larger transverse thickness, thus reducing the Gate-Induced Drain Leakage (GIDL) current.

In the CIS pixel readout structure according to embodiment 1, the SF and the SG adopt the asymmetric spacer structure, so that the pitch CT1 from the lower end of the source metal plug of the SG to the SG gate poly can be reduced while keeping the pitch CT2 from the lower end of the drain metal plug of the SF to the SF gate poly unchanged, thus reducing the pitch from the drain connecting point of the SF to the source connecting point of the SG. Since the source of the SG is not connected with working voltage Vdd and it is not influenced by leakage, not only can the Gate-Induced Drain Leakage (GIDL) current be maintained, but also the parasitic resistance can be reduced. Without changing its effective size (length and width of the device), it can reduce the parasitic resistance effect while reducing the area of the combined structure of the SF and the SG, thus effectively improving the transconductance (Gm) and reducing the imaging noise.

### Embodiment 2

Based on the CIS pixel readout structure according to embodiment 1, a source N+ (N-type heavily doped) area is formed on a surface of the P-well on the left side of the left spacer of the SG gate poly.

A lower end of the source metal plug of the SG is connected to the source N+ area.

A drain N+ area is formed on a surface of the P-well on the right side of the right spacer of the SF gate poly.

A lower end of the drain metal plug of the SF is connected to the drain N+ area.

In some embodiments, the pitch CT1 from the lower end of the source metal plug of the SG to the SG gate poly is less than the pitch CT2 from the lower end of the drain metal plug of the SF to the SF gate poly. An asymmetric contact to poly (CT to poly) pitch design is adopted. Contacts of the SG and the SF to poly (CT to poly) adopt different pitches. Since the source of the SG is not connected with working voltage Vdd, it is not influenced by leakage. The pitch from the source metal plug of the SG to the gate poly is small, thus reducing the parasitic resistance. The pitch from the drain metal plug of the SF to the gate poly is large, thus reducing the Gate-Induced Drain Leakage (GIDL) current.

In some embodiments, the space between the SG gate poly and the SF gate poly is less than 500 Å. The space between the SG gate poly and the SF gate poly is reduced, thus reducing the parasitic resistance of the share active area (share AA).

In some embodiments, the left spacer of the SG gate poly is formed by transversely stacking a first spacer oxide layer 151 on a first spacer SiN layer 152.

The right spacer of the SF gate poly is formed by transversely stacking a first spacer SiN layer 152 on a second spacer oxide layer 153 and then transversely stacking a first spacer oxide layer 151.

In some embodiments, the transverse thickness of the second spacer oxide layer is 10 Å-500 Å.

### Embodiment 3

Provided is a method for fabricating a CIS pixel readout structure, which includes the following steps:

In S0, a P-well process is performed on a semiconductor substrate to form a common P-well for a source follower transistor (SF) and a select transistor (SG).

In S1, referring to FIG. 4, a gate oxide layer 110, a poly layer 120 and a hard mask layer 130 are sequentially formed on the semiconductor substrate.

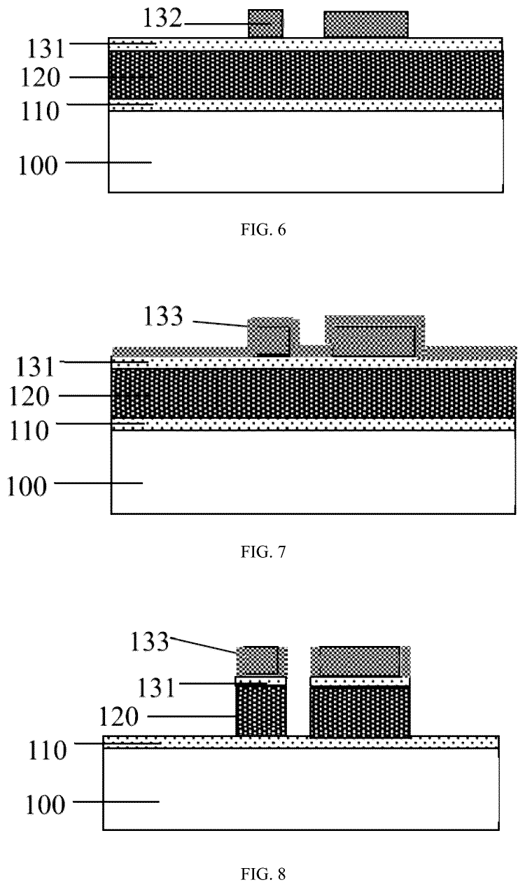

In S2, referring to FIG. 5 and FIG. 6, a photolithography process and etching are performed, and the poly layer 120 around an SF gate area and an SG gate area is removed to form gate structures. The SG gate structure is located on a left side of the SF gate structure. A space exists between the SG gate structure and the SF gate structure. The left-right width L2 of the SF gate structure is greater than the left-right width L1 of the SG gate structure.

In S3, referring to FIG. 11, a first spacer oxide layer 151 is deposited. The first spacer oxide layer 151 fills the space between the SG gate structure and the SF gate structure.

In S4, a first spacer SiN layer 152 is deposited.

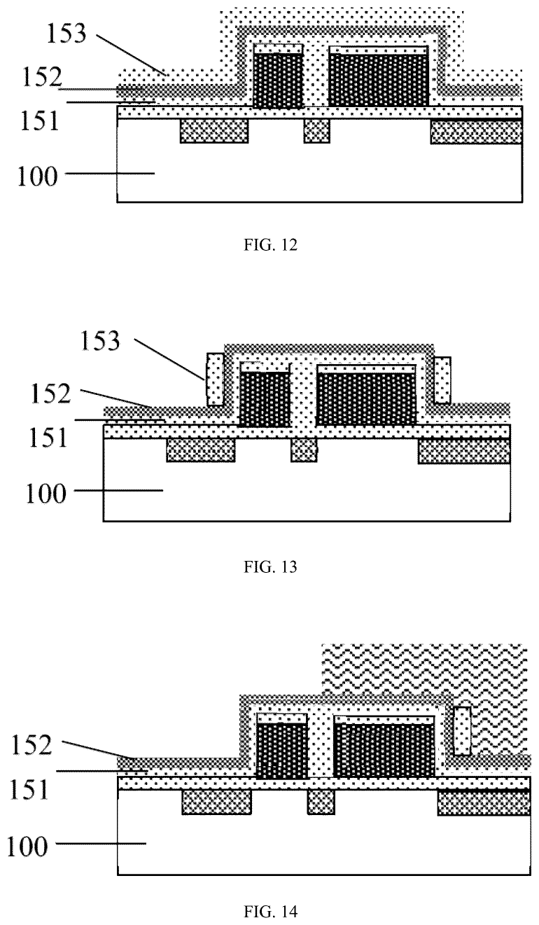

In S5, referring to FIG. 12, a second spacer oxide layer 153 is deposited to form an oxide-nitride-oxide spacer stack (ONO spacer film) structure.

In S6, referring to FIG. 13, the second spacer oxide layer 153 is etched till the first spacer SiN layer 152, the second spacer oxide layer 153 on side surfaces of the gate structures is reserved, and the second spacer oxide layer 153 at other positions is removed.

In S7, referring to FIG. 14 and FIG. 15, a photolithography process and wet etching are performed by using the first spacer SiN layer 152 as a stop layer, the second spacer oxide layer 153 on the side surface of the SG gate structure is removed, and the second spacer oxide layer 153 on the side surface of the SF gate structure is reserved to form an asymmetric structure.

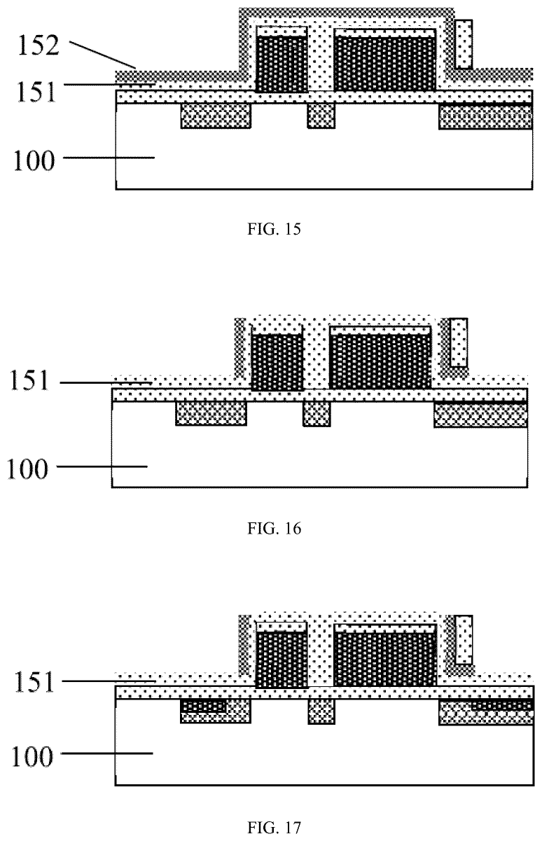

In S8, referring to FIG. 16, the first spacer SiN layer 152 is etched, the first spacer SiN layer 152 on the side surfaces of the gate structures is reserved, and the first spacer SiN layer 152 at other positions are removed to form an asymmetric spacer structure on a left side of the SG gate structure and a right side of the SF gate structure. A spacer on the left side of the SG gate structure is formed by transversely stacking a first spacer oxide layer 151 on a first spacer SiN layer 152. A spacer on the right side of the SF gate structure is formed by transversely stacking a first spacer SiN layer 152 on a second spacer oxide layer 153 and then transversely stacking a first spacer oxide layer 151. A difference between the transverse thicknesses of the spacers of the SG gate structure and the SF gate structure is defined through the second spacer oxide layer 153.

In S9, referring to FIG. 21, a drain metal plug and a gate metal plug of the SF, and a source metal plug and a gate metal plug of the SG are formed.

The drain metal plug of the SF is located on a right side of a right spacer of the SF and used for being externally connected with working voltage Vdd.

The gate metal plug of the SF is communicated to the poly layer 120 of the SF.

The source metal plug of the SG is located on a left side of a left spacer of the SG and used for outputting CIS pixel readout voltage Vout.

The gate metal plug of the SG is communicated to the poly layer 120 of the SG.

In S10, subsequent processes are performed, which are the same as standard logic processes.

In some embodiments, the pitch CT1 from a lower end of the source metal plug of the SG to the poly layer 120 of the SG is less than the pitch CT2 from a lower end of the drain metal plug of the SF to the poly layer 120 of the SF. An asymmetric contact to poly (CT to poly) pitch design is adopted. Different pitches are adopted from contacts of the SG and the SF to poly (CT to poly). Since the source of the SG is not connected with working voltage Vdd, it is not influenced by leakage.

In the method for fabricating the CIS pixel readout structure according to embodiment 3, the SF and the SG adopt the asymmetric spacer structure, so that the pitch CT1 from the lower end of the source metal plug of the SG to the poly layer 120 of the SG can be reduced while keeping the pitch CT2 from the lower end of the drain metal plug of the SF to the poly layer 120 of the SF unchanged, thus reducing the pitch from the drain connecting point of the SF to the source connecting point of the SG. Since the source of the SG is not connected with working voltage Vdd and it is not influenced by leakage, not only can the Gate-Induced Drain Leakage (GIDL) current be maintained, but also the parasitic resistance can be reduced. Without changing its effective size (length and width of the device), it can reduce the parasitic resistance effect while reducing the area of the combined structure of the SF and the SG, thus effectively improving the transconductance (Gm) and reducing the imaging noise.

### Embodiment 4

Based on the method for fabricating the CIS pixel readout structure according to embodiment 3, referring to FIG. 4, in step S1, the hard mask layer 130 is a composite structure formed by stacking a mask SiN layer 132 on a mask oxide layer 131.

In some embodiments, step S2 includes the following steps:

In S21, referring to FIG. 5 and FIG. 6, a photolithography process is performed and the mask SiN layer 132 is etched till the mask oxide layer 131.

In S22, referring to FIG. 7, a space SiN layer 133 is deposited.

In S23, the space SiN layer 133 is etched till the mask oxide layer 131 to cover a peripheral side of the mask SiN layer 132 with the space SiN layer 133.

In S24, referring to FIG. 8, the mask oxide layer 131 and the poly layer 120 are etched till the gate oxide layer 110 to form gate structures.

Through this process, the space between the SG gate poly and the SF gate poly can be reduced, thus reducing the parasitic resistance effect of the share active region (share AA), reducing the overall area of the CIS pixel readout structure while keeping the effective size (L1 and L2) of the SG and the SF unchanged, and improving the effective Gm of the combined structure of the SF and the SG The main purpose of this process step is to solve the problem of insufficient photolithography resolution caused by insufficient process nodes through this solution when the pitch from poly to poly exceeds the photolithography process capacity of the current process technology node, without requiring the mask and photoresist to be upgraded.

In some embodiments, after step S24, Rapid Thermal Oxidation (RTO) treatment is firstly performed on gate poly to form side protection for the gate poly and repair etching damage of the gate poly, and then step S3 is performed.

In some embodiments, the space between the SG gate structure and the SF gate structure is less than 500 Å.

In some embodiments, the transverse thickness of the second spacer oxide layer is 10 Å-500 Å.

### Embodiment 5

Based on the method for fabricating the CIS pixel readout structure according to embodiment 3, after step S2, a self-aligned LDD implantation process is performed by using a hard mask layer 130 to form a drain LDD of the SF on a surface of the P-well 100 at a right end of the SF gate structure and form a source LDD of the SG on a surface of the P-well 100 at a left end of the SG gate structure; then step S3 is performed.

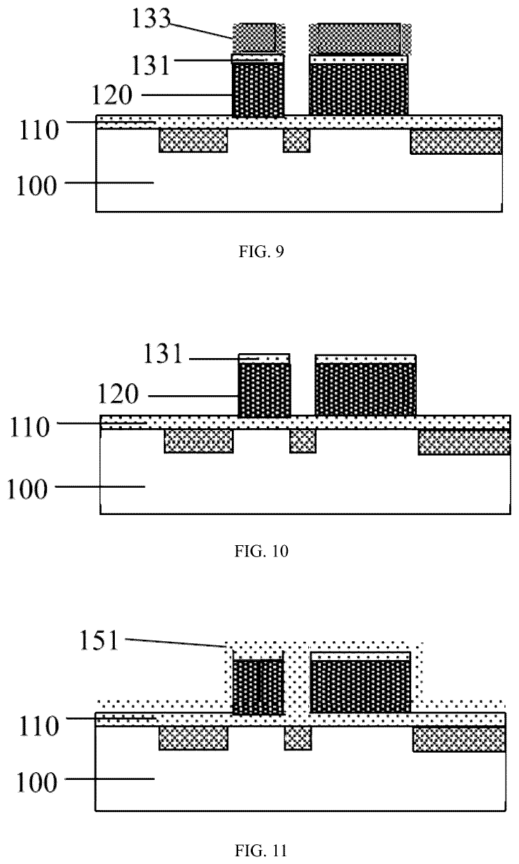

Referring to FIG. 9, after step S2, a self-aligned LDD implantation process is performed by using a hard mask layer 130 to form a drain LDD of the SF on a surface of the P-well 100 at a right end of the SF gate structure and form a source LDD of the SG on a surface of the P-well 100 at a left end of the SG gate structure; then step S3 is performed.

In some embodiments, referring to FIG. 10, after LDD implantation is completed, SiN is removed through wet etching; then step S3 is performed.

### Embodiment 6

Based on the method for fabricating the CIS pixel readout structure according to embodiment 5, step S9 includes the following steps:

Step S9 includes the following steps:

In S91, referring to FIG. 17, N+ (N-type heavily doped) ion implantation is performed by adopting a self-alignment method to form a drain N+ area of the SF on a surface of the drain LDD of the SF and form a source N+ area of the SG on a surface of the source LDD of the SG; different pitches from the drain N+ area of the SF and the source N+ area of the SG to a channel are defined through a difference between the transverse thickness of the spacer on the right side of the SF and the transverse thickness of the spacer on the left side of the SG.

In S92, referring to FIG. 21, through an interlayer dielectric process and a contact process, a drain metal plug of the SF communicated to the drain N+ area on the right side of the right spacer of the SF is formed;
a gate metal plug of the SF communicated to the SF gate poly is formed above the SF gate poly;
a source metal plug of the SG communicated to the source N+ area is formed on the left side of the left spacer of the SG; and
a gate metal plug of the SG communicated to the SG gate poly is formed above the SG gate poly.

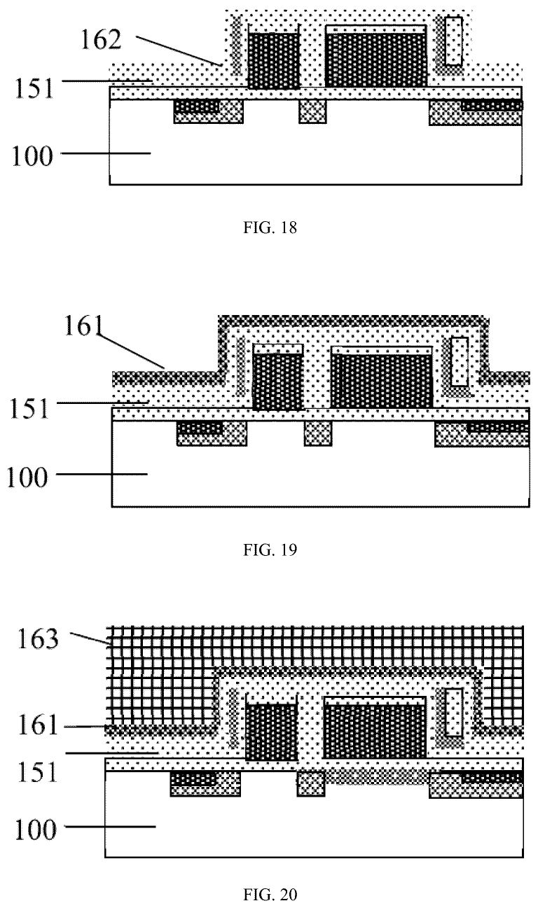

In some embodiments, referring to FIG. 18, FIG. 19 and FIG. 20, in step S92, the interlayer dielectric process includes firstly depositing a silicide-blocked (SAB) oxide layer 162; then depositing a Contact Etch Stop Layer (CESL) 161; and then depositing an ILD (interlayer dielectric) 163 and performing chemical-mechanical polishing.

In the method for fabricating the CIS pixel readout structure according to embodiment 6, the pitch from the corresponding N+ (N-type heavily doped) ion implantation to the channel is also achieved through asymmetric spacers, so that the pitch CT1 from the lower end of the source metal plug of the SG to the poly layer 120 of the SG can be reduced while keeping the pitch CT2 from the lower end of the drain metal plug of the SF to the poly layer 120 of the SF unchanged, thus reducing the pitch from the drain connecting point of the SF to the source connecting point of the SG. Since the source of the SG is not connected with working voltage Vdd and it is not influenced by leakage, not only can the Gate-Induced Drain Leakage (GIDL) current be maintained, but also the parasitic resistance can be reduced.

What are described above are only exemplary embodiments of this application, and are not intended to limit this application. Any modifications, equivalent replacements, improvements and the like made within the spirit and principle of this application shall be all included in the scope of protection of this application.

What is claimed is:

1. A CIS pixel readout structure, wherein a P-well is formed at an upper part of a semiconductor substrate;
SF gate poly and SG gate poly are formed on the P-well;
the SG gate poly is located on a left side of the SF gate poly; a space exists between the SG gate poly and the SF gate poly, and the left-right width of the SF gate poly is greater than the left-right width of the SG gate poly;
the space is filled with silicon oxide;
the transverse thickness of a spacer on a right side of the SF gate poly is greater than the transverse thickness of a spacer on a left side of the SG gate poly;
a drain metal plug of an SF is formed on a right side of a right spacer of the SF and used for being externally connected with working voltage;
a gate metal plug of the SG communicated to the SF gate poly is formed above the SF gate poly;
a source metal plug of an SG is formed on a left side of a left spacer of the SG and used for outputting CIS pixel readout voltage;
a gate metal plug of the SG communicated to the SG gate poly is formed above the SG gate poly.

2. The CIS pixel readout structure according to claim 1, wherein
a source N+ area is formed on a surface of the P-well on the left side of the left spacer of the SG gate poly;
a lower end of the source metal plug of the SG is connected to the source N+ area;
a drain N+ area is formed on a surface of the P-well on the right side of the right spacer of the SF gate poly;
a lower end of the drain metal plug of the SF is connected to the drain N+ area.

3. The CIS pixel readout structure according to claim 1, wherein the pitch from the lower end of the source metal plug of the SG to the SG gate poly is less than the pitch from the lower end of the drain metal plug of the SF to the SF gate poly.

4. The CIS pixel readout structure according to claim 1, wherein
the left spacer of the SG gate poly is formed by transversely stacking a first spacer oxide layer on a first spacer SiN layer;
the right spacer of the SF gate poly is formed by transversely stacking a first spacer SiN layer on a second spacer oxide layer and then transversely stacking a first spacer oxide layer;
the transverse thickness of the second spacer oxide layer is 10 Å-500 Å;
the space between the SG gate poly and the SF gate poly is less than 500 Å.

5. A method for fabricating a CIS pixel readout structure, wherein the method for fabricating the CIS pixel readout structure comprises the following steps:
S0: performing a P-well process on a semiconductor substrate to form a common P-well for an SF and an SG;
S1: sequentially forming a gate oxide layer, a poly layer and a hard mask layer on the semiconductor substrate;
S2: performing a photolithography process and etching, and removing the poly layer around an SF gate area and an SG gate area to form gate structures, the SG gate structure being located on a left side of the SF gate structure; a space existing between the SG gate structure and the SF gate structure, the left-right width of the SF gate structure being greater than the left-right width of the SG gate structure;
S3: depositing a first spacer oxide layer, the first spacer oxide layer filling the space between the SG gate structure and the SF gate structure;
S4: depositing a first spacer SiN layer;
S5: depositing a second spacer oxide layer;
S6: etching the second spacer oxide layer till the first spacer SiN layer, reserving the second spacer oxide layer on side surfaces of the gate structures, and removing the second spacer oxide layer at other positions;
S7: performing a photolithography process and wet etching by using the first spacer SiN layer as a stop layer, removing the second spacer oxide layer on the side surface of the SG gate structure, and reserving the second spacer oxide layer on the side surface of the SF gate structure to form an asymmetric structure;
S8: etching the first spacer SiN layer, reserving the first spacer SiN layer on the side surfaces of the gate structures, and removing the first spacer SiN layer at other positions to form an asymmetric spacer structure on a left side of the SG gate structure and a right side of the SF gate structure, a spacer on the left side of the SG gate structure being formed by transversely stacking a first spacer oxide layer on a first spacer SiN layer, a spacer on the right side of the SF gate structure being formed by transversely stacking a first spacer SiN layer on a second spacer oxide layer and then transversely stacking a first spacer oxide layer;
S9: forming a drain metal plug and a gate metal plug of the SF, and a source metal plug and a gate metal plug of the SG;
the drain metal plug of the SF being located on a right side of a right spacer of the SF and used for being externally connected with working voltage;
the gate metal plug of the SG being communicated to the poly layer of the SF;
the source metal plug of the SG being located on a left side of a left spacer of the SG and used for outputting CIS pixel readout voltage;
the gate metal plug of the SG being communicated to the poly layer of the SG; and
S10: performing subsequent processes.

6. The method for fabricating the CIS pixel readout structure according to claim 5, wherein the pitch from a lower end of the source metal plug of the SG to the poly layer of the SG is less than the pitch from a lower end of the drain metal plug of the SF to the poly layer of the SF.

7. The method for fabricating the CIS pixel readout structure according to claim 5, wherein in step S1, the hard mask layer is a composite structure formed by stacking a mask SiN layer on a mask oxide layer.

8. The method for fabricating the CIS pixel readout structure according to claim 5, wherein step S2 comprises the following steps:
S21: performing a photolithography process and etching the mask SiN layer till the mask oxide layer;
S22: depositing a space SiN layer;
S23: etching the space SiN layer till the mask oxide layer to cover a peripheral side of the mask SiN layer with the space SiN layer; and
S24: etching the mask oxide layer and the poly layer till the gate oxide layer to form gate structures.

9. The method for fabricating the CIS pixel readout structure according to claim 8, wherein after step S24, rapid thermal oxidation treatment is firstly performed on gate poly to form side protection for the gate poly and repair etching damage of the gate poly, and then step S3 is performed.

10. The method for fabricating the CIS pixel readout structure according to claim 5, wherein the space between the SG gate structure and the SF gate structure is less than 500 Å.

11. The method for fabricating the CIS pixel readout structure according to claim 5, wherein the transverse thickness of the second spacer oxide layer is 10 Å-500 Å.

12. The method for fabricating the CIS pixel readout structure according to claim 5, wherein after step S2, a self-aligned LDD implantation process is performed by using a hard mask layer 130 to form a drain LDD of the SF on a surface of the P-well at a right end of the SF gate structure and form a source LDD of the SG on a surface of the P-well at a left end of the SG gate structure; then step S3 is performed.

13. The method for fabricating the CIS pixel readout structure according to claim 12, wherein after LDD implantation is completed, SiN is removed through wet etching; then step S3 is performed.

14. The method for fabricating the CIS pixel readout structure according to claim 12, wherein step S9 comprises the following steps:
S91: performing N+ ion implantation by adopting a self-alignment method to form a drain N+ area of the SF on a surface of the drain LDD of the SF and form a source N+ area of the SG on a surface of the source LDD of the SG; defining different pitches from the drain N+ area of the SF and the source N+ area of the SG to a channel through a difference between the transverse thickness of the spacer on the right side of the SF and the transverse thickness of the spacer on the left side of the SG; and
S92: through an interlayer dielectric process and a contact process, forming a drain metal plug of the SF communicated to the drain N+ area on the right side of the right spacer of the SF;
forming a gate metal plug of the SF communicated to the SF gate poly above the SF gate poly;
forming a source metal plug of the SG communicated to the source N+ area on the left side of the left spacer of the SG; and
forming a gate metal plug of the SG communicated to the SG gate poly above the SG gate poly.

15. The method for fabricating the CIS pixel readout structure according to claim 14, wherein in step S92, the interlayer dielectric process comprises firstly depositing a silicide-blocked oxide layer; then depositing a contact etch stop layer; and then depositing an ILD and performing chemical-mechanical polishing.
